(19) United States
(12) Patent Application Publication
(10) Pub. No.: US 2015/0138734 A1
(43) Pub. Date: May 21, 2015

(54) 360 DEGREE DIRECT COOLED POWER MODULE

(71) Applicant: MAGNA ELECTRONICS INC., Auburn Hills, MI (US)

(72) Inventor: Yuanbo Guo, Troy, MI (US)

(21) Appl. No.: 14/535,740

(22) Filed: Nov. 7, 2014

Related U.S. Application Data
(60) Provisional application No. 61/905,463, filed on Nov. 18, 2013.

(51) Int. Cl. H05K 7/20; H05K 7/02; H05K 9/00; H02M 7/00

(52) U.S. Cl. CPC H05K 7/20945; H02M 7/003; H05K 7/02; H05K 9/0007
USPC 361/736

(57) ABSTRACT

A power module for a motor traction inverter system of a vehicle includes a body portion configured to be inserted into a cooling device and having circuitry established thereat that generates heat during operation of the power module. The body portion has a surface area that is disposed in the cooling device and provides 360 degree direct cooling of the power module around the body portion for cooling the circuitry during operation of the power module. The power module may be transfer molded into a shape with a head terminal for sealing at the cooling device, and electrical connections of the power module share only one side surface or end of the power module, with all other sides and surfaces of the power module being disposed in the cooling device and used for cooling. The power module may not include thermal grease layers and may or may not be insulated.

### CROSS REFERENCE TO RELATED APPLICATION

The present application claims the filing benefits of U.S. provisional application Ser. No. 61/905,463, filed Nov. 18, 2013, which is hereby incorporated herein by reference in its entirety.

### FIELD OF THE INVENTION

The present invention relates generally to electric or hybrid vehicles and, more particularly, to power modules for vehicles.

### BACKGROUND OF THE INVENTION

U.S. Pat. No. 7,759,778 discloses a transfer-mold power module with two large surface sides open for cooling. However, from the heat sink design (small cylinder type heat sinks) it can be determined that the module is not dipped into the coolant directly. The cooling area of the module is not fully utilized. Also, the electrical connections need two sides, making it much harder to seal if dipped in coolant. U.S. Design Pat. No. D651,565 shows a metal shell/case with similar geometry. The power module will be inserted into this case from the opening and contacting the case surface through thermal gap pads. It is double side cooling, but not direct cooling. Thermal gap pads have similar thermal conductivity, if not worse, to thermal grease.

### SUMMARY OF THE INVENTION

The present invention provides a power module that is configured to provide 360 degree direct cooling. The power module of the present invention utilizes as much surface area as possible for heat dissipation. The module of the present invention is transfer molded into a shape with a head terminal for sealing at a cooling device that receives the body portion of the power module therein. All electrical connections share only one side (small surface side) of the power module, leaving all other sides for cooling. The power module eliminates the thermal grease layers.

A method or system of the present invention includes a cooling device that may circulate cooling fluid or a cooling medium, with the cooling device being configured to receive a body portion of a power module that provides 360 degree direct cooling, with the electrical connections to circuitry of the power module being external the cooling device when the body portion is received therein. The cooling medium may comprise a dielectric medium, such that the power module may not include a dielectric layer at the body portion that is received in the cooling device and that contacts the dielectric medium circulated in the cooling device.

These and other objects, advantages, purposes and features of the present invention will become apparent upon review of the following specification in conjunction with the drawings.

### BRIEF DESCRIPTION OF THE DRAWINGS

FIGS. 1-3 are views of known power modules;

FIG. 4 shows views of a double side cooled and direct cooled power module in accordance with the present invention;

FIGS. 5 and 6 are views of inverter concepts of the present invention;

FIG. 7 is a perspective view of an insulated power module of the present invention; and

FIG. 8 is a perspective view of a non-insulated power module of the present invention.

### DESCRIPTION OF THE PREFERRED EMBODIMENTS

Power modules are the core components in a motor traction inverter system handling power conversion. Thermal management is a priority in power module design. Because the amount of power that a power module can handle is primarily limited by the temperature of the power module, reduced thermal resistance means that a smaller semiconductor chip area may be provided for higher power conversion. And because the semiconductor chip area is the main cost contributor in the power module, the chip area reduction leads to a cost reduction.

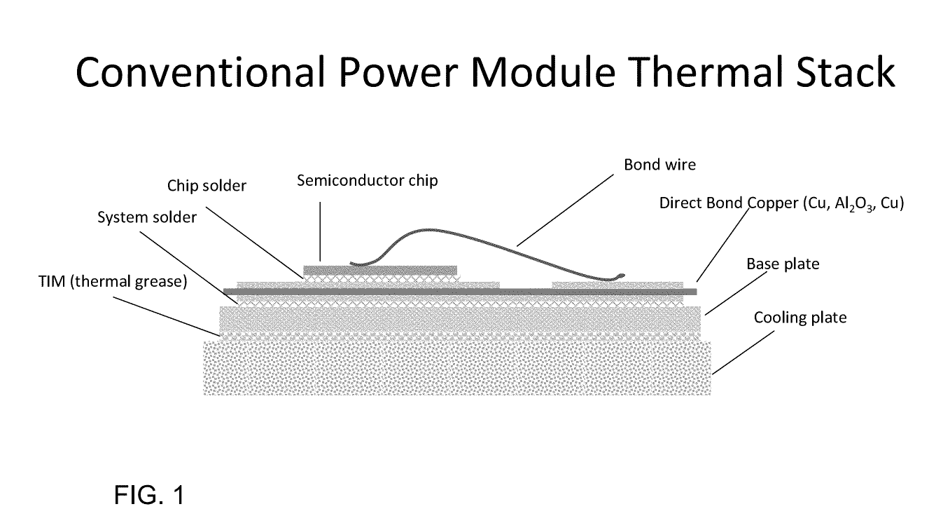

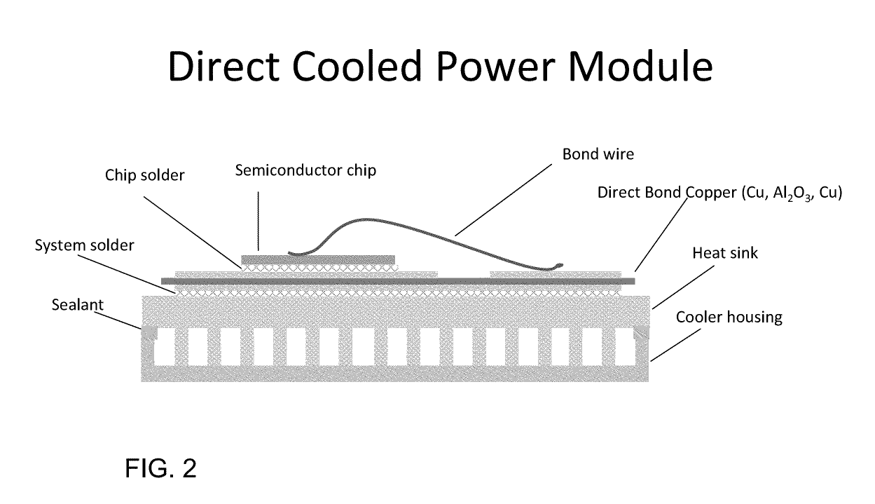

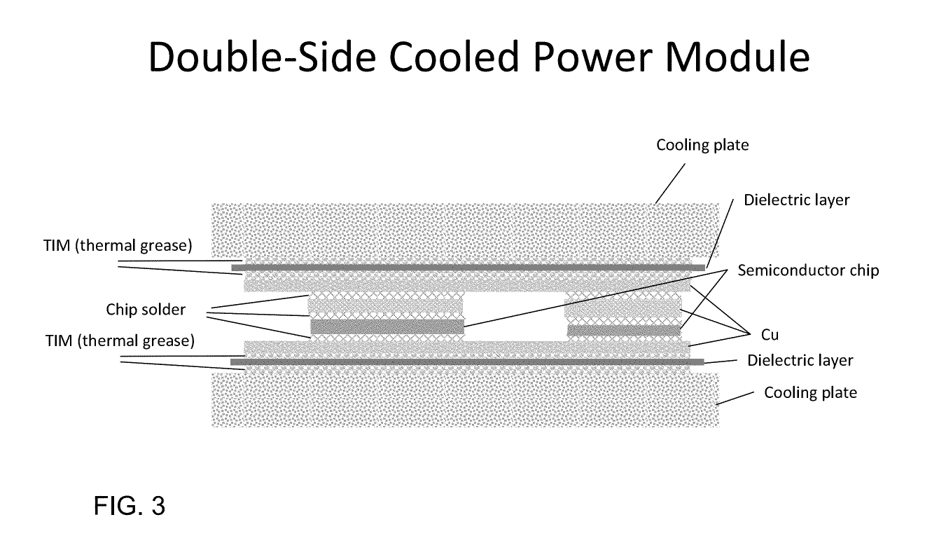

In a known power module structure (such as shown in FIG. 1), a layer of thermal grease (Thermal Interface Material or TIM) is used to attach the power module base plate to the cooler or cooling plate. However, the TIM introduces a large thermal resistance in the cooling path due to the low thermal conductivity of the thermal interface material. Generally, there are two common ways to overcome this issue. One is to use solder to attach the baseplate to a heat sink and dip the heat sink in the cooler directly, with a typical example of this being the Hybrid Pack power modules with pin fin heat sinks commercially available from Infineon. Such a power module (such as shown in FIG. 2) replaces the thermal grease layer with a solder layer, which has much higher thermal conductivity. However, it does not fully utilize the large surfaces of the power module to dissipate heat (only one side is used to dissipate heat). A second known solution is to expose the other side of the power module for heat dissipation, with a typical example of this being the Denso double-side cooled power modules such as are in use in the MY 2008 Lexus LS600h and MY 2013 Toyota Camry hybrid vehicles (such as shown in FIG. 3). However, a concern with this is that both sides need thermal grease layers to attach to the cooler. These two kinds of solutions are reported to give similar thermal performance improvement comparing to traditional structure, about 20%-30% thermal resistance reduction.

The proposed solution of the present invention eliminates the thermal grease layers and at the same time utilizes as much surface area as possible for heat dissipation. The module of the present invention is transfer molded into a shape with a head terminal for sealing at the cooling device when the body portion is disposed in the cooling device. All electrical connections share only one side (small surface side) of the power module, leaving all other sides for cooling.

An additional thermal improvement can be made if the coolant can be changed to dielectric coolant, so that the dielectric layer on both sides of the power module can be removed. On one hand, this eliminates the second biggest thermal resistance layer—the dielectric layer, and on the other hand, the material cost as well as manufacturing cost of the power module will be reduced or lowered.

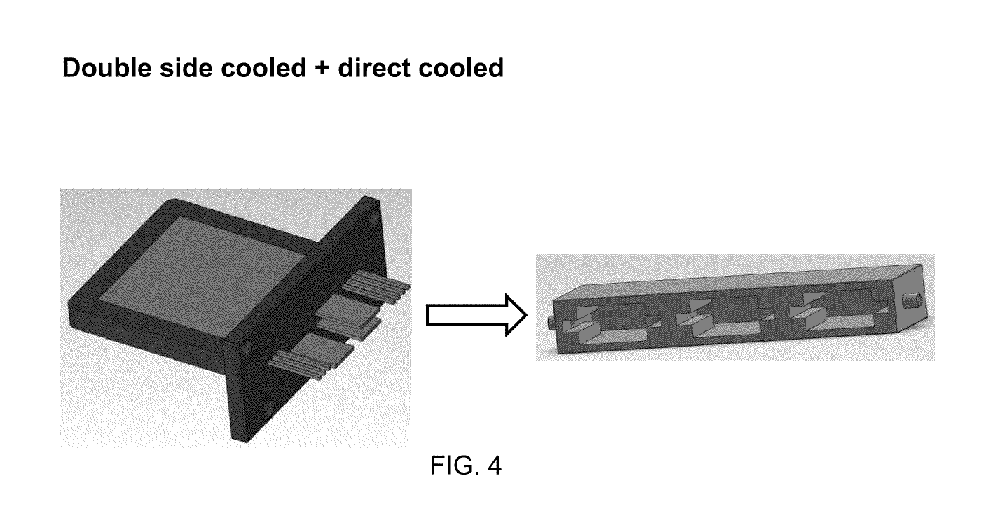

As shown in FIG. 4, a double side cooled and direct cooled power module has double-side copper exposure and may be insulated or not insulated. The power module may or may not include heat sinks. Optionally, the surface or surfaces may be roughened to increase the surface area, such as for a lower or reduced power version of the power module. Optionally, the double side heat sink attachment may be made by solder or silver sintering, such as for a higher or increased power version of the power module.

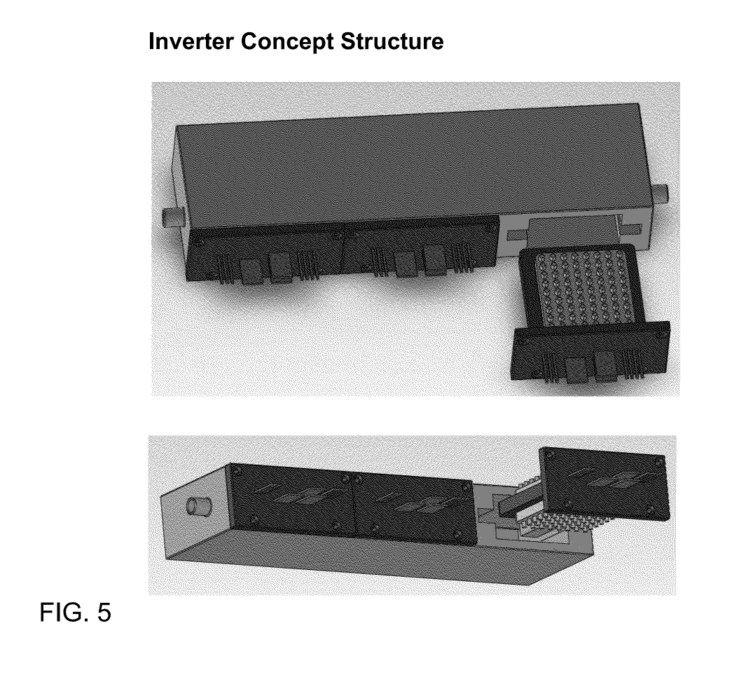

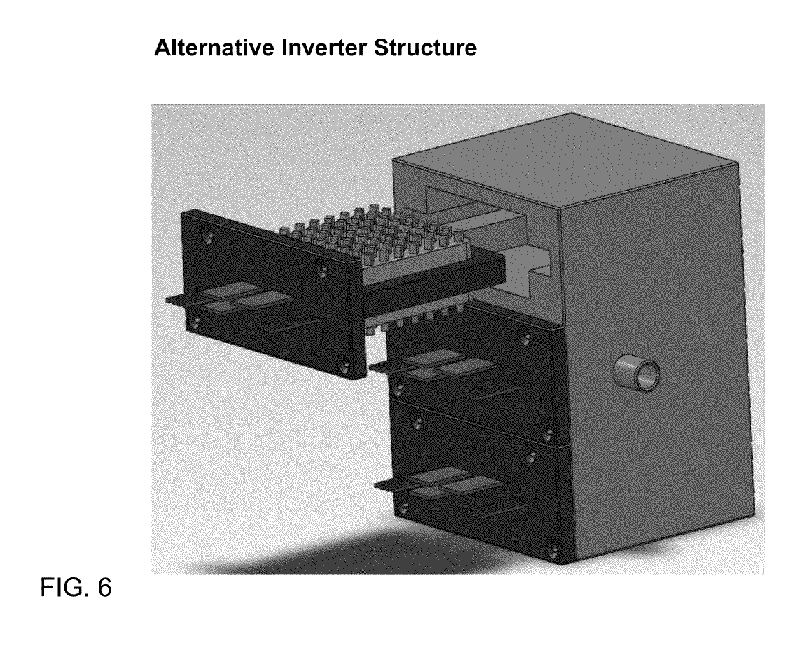

As shown in FIGS. 5 and 6, inverter concept structures provide for double-side pin-fin cooling of the power module. As shown in FIG. 5, the body portion is configured to be inserted into a cooler or cooling device (that may have cooling fluid or the like circulated therein), with the terminals (for electrically connecting to the power module circuitry) exposed at the connecting end of the power module that is external of the cooling device. When the body portion is received in the cooling device, the head terminal mates against or engages and seals against the outer surface of the cooling device to limit coolant leakage during operation of the power module and cooling of the circuitry of the power module.

The power module structure of the present invention does not include a thermal grease layer (or other similar high thermal impedance layer). The structure includes extra cooler area for the gate drive board, capacitors and busbars. The shielded power module reduces or mitigates electromagnetic interference (EMI) concerns (to limit or reduce EMI during operation of the power module). The cooler may have slots or similar structural configurations to resist thermal-induced deformation of the power modules and also to simplify the inverter assembly process.

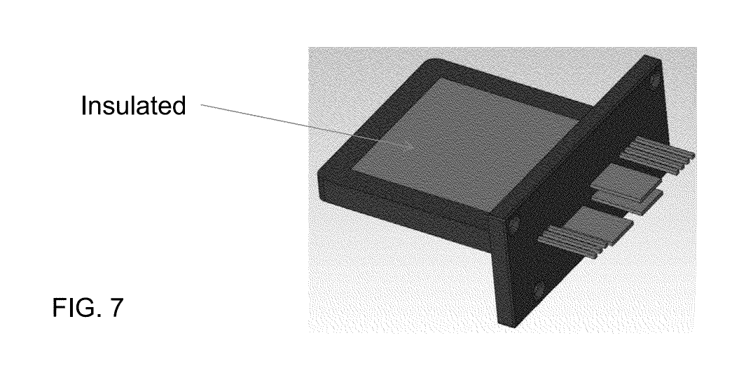

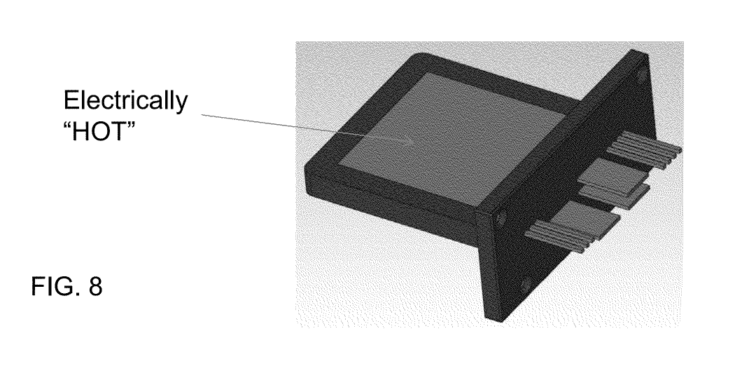

The power module of the present invention may be insulated or non-insulated. For example, and with reference to FIG. 7, an insulated power module may be used with standard coolant. Such an insulated power module may have compromised thermal impedance and may cost more as compared to a non-insulated version, such as discussed below with respect to FIG. 8. The advantages of the insulated power module concept of FIG. 7 include that the power module provides double-side pin-fin cooling (360 degree true direct cooling), and the power module does not include a thermal grease layer (or other similar high thermal impedance layer). The scalable power modules of this type may be made using available technology and the structure includes extra cooler area for the gate drive board, capacitors and busbars. The power module also includes improved EMI shielding and reduced parasitic inductance. Optionally, a light weight cooler may be provided because it does not have to be made of metal and thus may be formed of a non-metallic material.

Optionally, the power module of the present invention may be non-insulated. For example, and with reference to FIG. 8, a non-insulated power module is used with a dielectric coolant. Such a non-insulated power module may have lower or reduced thermal impedance and may cost less as compared to the insulated version, such as discussed above. The advantages of the non-insulated power module concept of FIG. 8 include that the power module provides double-side pin-fin cooling (360 degree true direct cooling), and the power module does not include a thermal grease layer (or other similar high thermal impedance layer). The scalable power modules of this type may be made using available technology and the structure includes extra cooler area for the gate drive board, capacitors and busbars. The power module also includes improved EMI shielding and reduced parasitic inductance. Optionally, a light weight cooler may be provided because it does not have to be made of metal. Also, the power module does not include a dielectric layer (the second highest thermal impedance layer).

Thus, the benefits of the power modules of the present invention include:
Double side direct cooling, which provides enhanced heat dissipation and leads to power semiconductor cost reduction (up to about 50 percent thermal resistance reduction comparing with single side cooled module using thermal grease);
Extra cooler surface exposed can be used for capacitor, busbars, and gate drive board cooling, which may lead to a cost reduction on those cooled components;
The cooler can be made from composite materials which are much lighter than metal and thus lead to a system weight reduction;
The power modules become more scalable to adapt different power level applications because of the better thermal control;
The power modules of the present invention help to mitigate EMI problems if a metal cooler to be used;
Simplified or enhanced power module assembly by transfer molding the module with a sealing terminal;
Simplified or enhanced inverter power stage assembly by channel-assisted module insertion to the cooler; and/or
Possibly less coolant leakage issues because there is a smaller area to be sealed.

Changes and modifications in the specifically described embodiments may be carried out without departing from the principles of the present invention, which is intended to be limited only by the scope of the appended claims as interpreted according to the principles of patent law.

1. A power module for a motor traction inverter system of a vehicle, said power module comprising:
a body portion configured to be inserted into a cooling device;
wherein said body portion has circuitry established thereat and wherein said circuitry generates heat during operation of said power module; and
wherein said body portion has a surface area that provides 360 degree direct cooling of said power module around said body portion for cooling said circuitry during operation of said power module.

2. The power module of claim 1, wherein said power module is transfer molded into a shape with a head terminal for sealing against a portion of the cooling device when said body portion is disposed in the cooling device.

3. The power module of claim 2, wherein said head terminal is at an end of said body portion and wherein all other sides and surfaces of said body portion are used for cooling said circuitry during operation of said power module and when said body portion is disposed in the cooling device.

4. The power module of claim 1, wherein electrical connections of said power module share only one surface of said power module, and wherein all other sides and surfaces of said power module are used for cooling said circuitry during operation of said power module and when said body portion is disposed in the cooling device.

5. The power module of claim 1, wherein said power module does not include thermal grease layers.

6. The power module of claim 1, wherein said power module does not include a dielectric layer.

7. The power module of claim 1, wherein said power module is insulated.

8. The power module of claim 1, wherein said power module is non-insulated.

9. The power module of claim 1, wherein said body portion comprises a generally planar element having opposite surfaces used for cooling.

10. The power module of claim 9, wherein said opposite surfaces are textured to increase the surface area of said opposite surfaces.

11. The power module of claim 10, wherein said opposite surfaces comprise a plurality of protrusions protruding outward from said body portion.

12. The power module of claim 1, wherein said circuitry is established at a semiconductor chip of said body portion.

13. The power module of claim 1, wherein said power module is shielded to limit electromagnetic interference during operation of said power module.

14. A power module for a motor traction inverter system of a vehicle, said power module comprising:
a body portion configured to be inserted into a cooling device;
wherein circuitry is established at a semiconductor chip of said body portion and wherein said circuitry generates heat during operation of said power module;
a terminal at an end of said body portion for electrically connecting to said circuitry of said power module, wherein said end of said body portion is not disposed in the cooling device when said body portion is inserted into the cooling device; and
wherein all other surfaces of said body portion except said end are disposed in the cooling device to provide direct cooling of said power module around said body portion for cooling said circuitry during operation of said power module.

15. The power module of claim 14, wherein said body portion comprises a generally planar element having opposite surfaces used for cooling.

16. The power module of claim 15, wherein said opposite surfaces are textured to increase the surface area of said opposite surfaces.

17. The power module of claim 16, wherein said opposite surfaces comprise a plurality of protrusions protruding outward from said body portion.

18. A power module for a motor traction inverter system of a vehicle, said power module comprising:
a body portion configured to be inserted into a cooling device;
wherein circuitry is established at a semiconductor chip of said body portion and wherein said circuitry generates heat during operation of said power module;
a terminal at an end of said body portion for electrically connecting to said circuitry of said power module, wherein said end of said body portion is not disposed in the cooling device when said body portion is inserted into the cooling device;
wherein all other surfaces of said body portion except said end are disposed in the cooling device to provide direct cooling of said power module around said body portion for cooling said circuitry during operation of said power module; and
wherein at least one of the surfaces of said body portion disposed in the cooling device comprises a plurality of protrusions protruding outward from said body portion.

19. The power module of claim 18, wherein said body portion comprises a generally planar element having opposite surfaces used for cooling.

20. The power module of claim 18, wherein said terminal end is configured to seal against an outer portion of the cooling device when said body portion is inserted into the cooling device.
